(19) United States
(12) Patent Application Publication
(10) Pub. No.: US 2002/0144640 A1
(43) Pub. Date: Oct. 10, 2002

(54) Method for increasing the light yield oxyorthosilicate compound scintillation crystals

(76) Inventors: Mark S. Andreaco, Knoxville, TN (US); Merry A. Spurrier, Maryville, TN (US); Charles W. Williams, Powell, TN (US); Charles L. Melcher, Oak Ridge, TN (US)

Correspondence Address: PITTS AND BRITTIAN P C, P O BOX 51295, KNOXVILLE, TN, 37950-1295, US

(21) Appl. No.: 09/827,860

(22) Filed: Apr. 6, 2001

(51) Int. Cl. C30B 1/00

(52) U.S. Cl. 117/2

(57) ABSTRACT

A method of improving the light yield of Oxyorthosilicate scintillation crystals, such as Lutetium Oxyorthosilicate, Yttrium Oxyorthosilicate, Lutetium Gadolinium Oxyorthosilicate or Lutetium Yttrium Oxyorthosilicate scintillation crystals. In accordance with the teachings of the preferred embodiment, the Oxyorthosilicate scintillation crystals are annealed in a atmosphere selected to be a reducing atmosphere or slightly oxidizing at a selected annealing temperature. In this regard, in the preferred embodiment, the Oxyorthosilicate scintillation crystals are heated in a furnace. During the annealing cycle, the temperature is ramped up from room temperature to the annealing temperature over a selected period of time. After a second selected period of time of sustaining the annealing temperature, the annealing temperature is then ramped down over for a selected period of time. Annealing Oxyorthosilicate scintillation crystals in this manner is shown to improve the scintillation efficiency of the Oxyorthosilicate scintillation crystal.

### CROSS-REFERENCE TO RELATED APPLICATIONS

Not Applicable STATEMENT REGARDING FEDERALLY SPONSORED RESEARCH OR DEVELOPMENT

Not Applicable

### BACKGROUND OF THE INVENTION

1. Field of Invention

This invention relates to crystals used for PET and SPECT imaging. More specifically, it relates to a method of increasing scintillation efficiency of Oxyorthosilicate compound scintillation crystals by reducing light traps in the crystals.

2. Description of the Related Art

Devices for detecting the distribution of gamma rays transmitted or emitted through objects to study the compositions or functions of the objects are well known to the art. The techniques referred to as Emission Computed Tomography can be divided into two specific classes; Single Photon Emission Computed Tomography (SPECT) uses radiotracers which emit gamma rays but do not emit positrons and Positron Emission Tomography (PET) which uses radiotracers that emit positrons. Therefore, the fundamental physical difference between the two techniques is that PET uses annihilation coincidence detection. In either discipline, scintillation crystals are utilized to detect the emitted gamma rays. Scintillation crystals are known to be grown using the Czochralski technique. It is further known to grow scintillation crystals from various compositions to achieve differing results. A number of scintillation crystals are composed of rare earth Oxyorthosilicate compounds such as Lutetium Oxyorthosilicate (LSO), Yttrium Oxyorthosilicate (YSO), Lutetium Gadolinium Oxyorthosilicate (LGSO) and Lutetium Yttrium Oxyorthosilicate (LYSO), commonly referred to herein as Oxyorthosilicate scintillation crystals.

It is an object of the present invention to provide a method of increasing the scintillation efficiency of Oxyorthosilicate scintillation crystals by annealing the Oxyorthosilicate scintillation crystals.

Another object of the present invention is to provide a method of increasing the scintillation efficiency of Oxyorthosilicate scintillation crystals by annealing Oxyorthosilicate scintillation crystals in a reducing, or slightly oxidizing, atmosphere.

Other objects and advantages over the prior art will become apparent to those skilled in the art upon reading the detailed description together with the drawings as described as follows.

### BRIEF SUMMARY OF THE INVENTION

In accordance with the teachings of the present invention a method of improving the scintillation efficiency of Oxyorthosilicate scintillation crystals by annealing the Oxyorthosilicate scintillation crystals in a reducing, or alternatively, oxidizing, atmosphere is disclosed. In this regard, in the preferred embodiment, the Oxyorthosilicate scintillation crystals, either boules or cut crystal slabs, are placed in an iridium crucible, in a spaced apart fashion to prevent the crystals from fusing together during the annealing cycle. The crucible is then placed in a furnace. It will be appreciated that a crucible may not be necessary depending upon the type of furnace utilized. During the annealing cycle, the temperature is ramped up linearly from room temperature to the annealing temperature, which in the preferred embodiment is between approximately 1400° C. and approximately 1800° C., over an approximately four or more hour period. For a 10 mm thick crystal, this temperature is sustained for approximately four hours or more. It will be appreciated that thicker crystals require longer hold times. The annealing temperature is then ramped down linearly over approximately a four or more hour period of time. Upon the Oxyorthosilicate scintillation crystals reaching room temperature, the crystals are removed from the furnace.

### BRIEF DESCRIPTION OF THE SEVERAL VIEWS OF THE DRAWINGS

The above-mentioned features of the invention will become more clearly understood from the following detailed description of the invention read together with the drawings in which:

FIG. 1 is a flow chart illustrating the steps in the preferred embodiment of the method of the present invention.

FIG. 2 is a table of test results showing the effectiveness of the method of the present invention.

FIG. 3 is a table of test results showing the effectiveness of the present method with crystals having a LYSO composition.

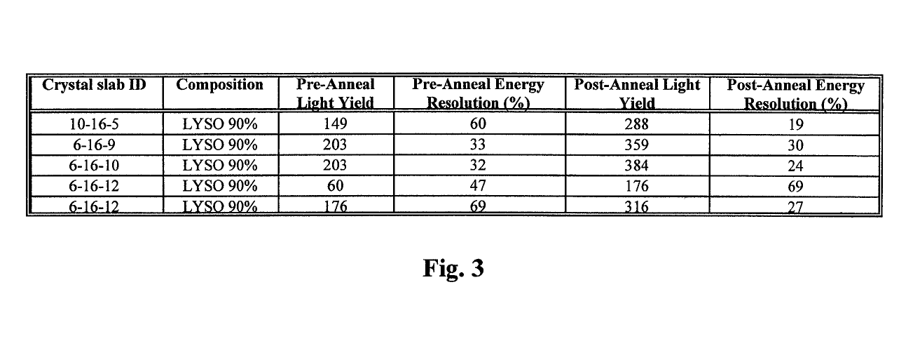

### DETAILED DESCRIPTION OF THE INVENTION

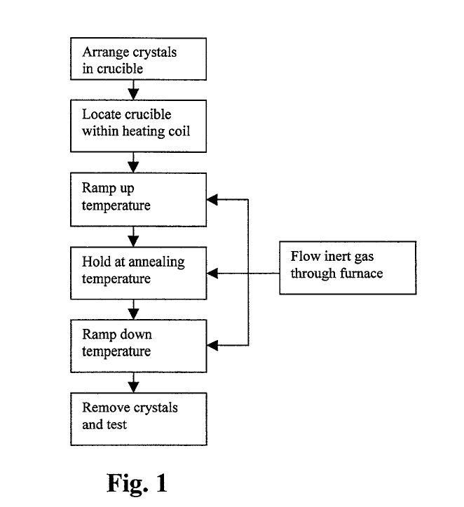

A preferred method for improving the scintillation efficiency of scintillation crystals composed of rare earth Oxyorthosilicate compounds, such as Lutetium Oxyorthosilicate (LSO), Yttrium Oxyorthosilicate (YSO), and Lutetium-Yttrium Oxyorthosilicate (LYSO) scintillation crystals is set forth in the flow chart illustrated in FIG. 1. According to the steps of the preferred method, the Oxyorthosilicate scintillation crystals to be annealed are arranged in an iridium crucible at step 20. It will be appreciated by those skilled in the art that the method of the present invention can be practiced on cut Oxyorthosilicate scintillation crystal slabs, or on a crystal boule after the crystal has been pulled. It will be appreciated that any identifying marks on the scintillation crystal will bum off in the furnace. Accordingly, if it is important to be able to identify individual crystals subsequent to the annealing cycle, the location of each crystal should be recorded in map fashion as the crystals are being loaded into the crucible. In order to prevent fusion of crystals in close proximity to one another, the crystals should be in spaced relation so as not to come into contact with each other. In the preferred embodiment, an iridium spacer is placed between each crystal in order to prevent adjacent crystals from coming into contact with each other. In the preferred embodiment, the Oxyorthosilicate scintillation crystals are arranged such that all of them are inside the crucible with substantially no portion of any crystal protruding above the top of the crucible so as to ensure that the crystals are heated evenly. Also in the preferred embodiment, an iridium washer is placed on top of the crucible in order to further improve the thermal environment within the crucible.

The crucible is then placed within a furnace chamber, preferably within the RF induction coil of an RF furnace, and the furnace chamber is sealed at step 40.

The temperature is ramped up in a linear manner from room temperature to the annealing temperature over a four or more hour period at step 60. The ramping time required varies with the crystal thickness with thicker crystals requiring a slower ramp time. A four hour ramp is generally adequate for each 10 mm thickness of crystal; eight to ten hours is acceptable for a 20 mm thick crystal. It will be appreciated that the ramp time can be shortened if an increased risk of cracking is acceptable.

Upon reaching the preferred annealing temperature of approximately 1400° C. to approximately 1800° C., the annealing temperature is maintained for a period of time of approximately four hours per 10 mm thickness of crystal. The temperature is then ramped down, at step 80, in a linear manner over a four hour period of time. As described above, it will be understood that a longer period of time is preferred for thicker crystals.

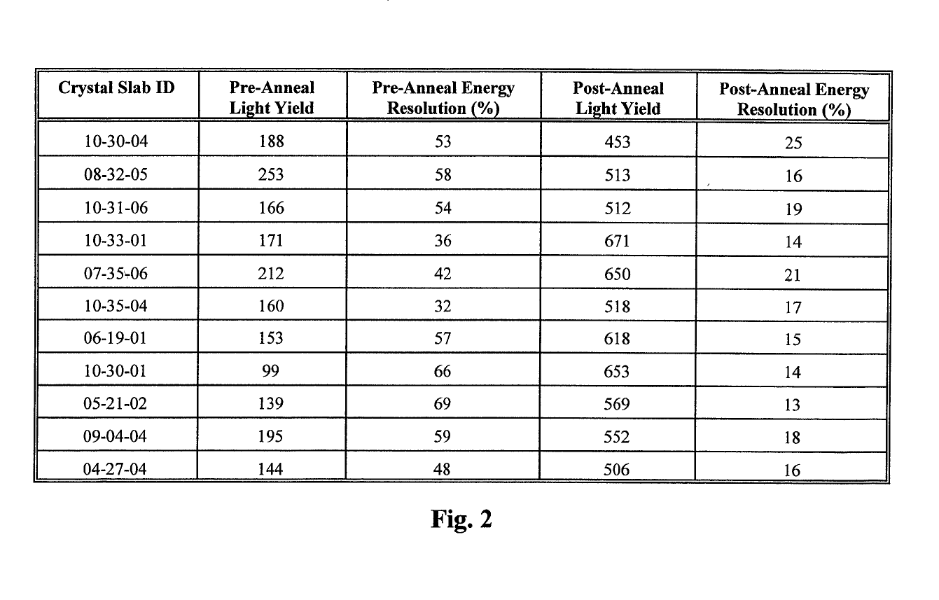

Upon returning to room temperature, the Oxyorthosilicate scintillation crystals are removed from the furnace. While not a necessary step in the annealing process, it will be understood that some oxyorthosilicate scintillation crystals are typically held in total darkness for hours prior to testing. As can be seen in referring to FIG. 2, the scintillation efficiency (or light yield) of the crystals is improved upon annealing. For instance, crystal slab 10-30-01 exhibited a pre-annealing light yield of 99 and a post-annealing light output of 653. It will be understood by those skilled in the art that light output is measured against a reference NaI(T1) crystal having a light output of 1000. Further, energy resolution, expressed as a percentage, was reduced from 66% to 14%. Annealing does not cure cracking defects, indeed, preexisting cracks exhibit a tendency to lengthen during annealing. And, while annealing does not appear to reduce banding, off-color slabs have been annealed with excellent results. In this regard, an orange slab became much lighter and a yellow slab became nearly colorless. However, it should be understood that the present method is also useful for increasing the scintillation efficiency, or light yield, of colorless Oxyorthosilicate scintillation crystals. Thus, while annealing has been shown to remove some color, the present method is not limited to annealing colored Oxyorthosilicate scintillation crystals. As stated above, the scintillation efficiency of colorless Oxyorthosilicate scintillation crystals can be improved by the method of the present invention.

From the foregoing description, it will be recognized by those skilled in the art that a method of increasing the scintillation efficiency of Oxyorthosilicate scintillation crystals has been provided. Specifically the present invention provides a method of increasing the scintillation efficiency of scintillation crystals by annealing the Oxyorthosilicate scintillation crystals.

While a preferred embodiment has been shown and described, it will be understood that it is not intended to limit the disclosure, but rather it is intended to cover all modifications and alternate methods falling within the spirit and the scope of the invention as defined in the appended claims.

Having thus described the aforementioned invention, we claim:

1. A method for improving the light yield of an Oxyorthosilicate compound scintillation crystal comprising the steps of;
arranging Oxyorthosilicate scintillation crystals to be annealed in furnace chamber in a selected, identifiable manner;
increasing temperature in said furnace chamber from room temperature to said annealing temperature over a selected period of time;
holding said temperature within said furnace chamber at said annealing temperature for a first selected period of time; and
decreasing said temperature within said furnace chamber to room temperature over a second selected period of time;
removing said Oxyorthosilicate scintillation crystals from said furnace.

2. The method of claim 1 wherein said Oxyorthosilicate scintillation crystal is selected from a group consisting of Lutetium Oxyorthosilicate, Yttrium Oxyorthosilicate, Lutetium Gadolinium Oxyorthosilicate and Lutetium Yttrium Oxyorthosilicate.

3. The method of claim 1 wherein said first selected period of time is approximately four hours per each 10 mm thickness of said Oxyorthosilicate scintillation crystal.

4. A method for improving the light yield of an Oxyorthosilicate scintillation crystal comprising the steps of;
arranging Oxyorthosilicate scintillation crystals to be annealed in a crucible in an selected, identifiable manner, wherein said Oxyorthosilicate scintillation crystals are in spaced relation so as to prevent crystals in close proximity to one another from fusing together;
locating said crucible within a furnace chamber;
increasing temperature in said furnace chamber linearly from room temperature to said selected annealing temperature over a selected period of time;
holding said temperature within said furnace chamber at said annealing temperature for approximately four hours per each 10 mm thickness of said Oxyorthosilicate scintillation crystal;
decreasing said temperature within said furnace chamber to room temperature over a selected period of time; and
removing said Oxyorthosilicate scintillation crystals from said furnace.

5. The method of claim 4 wherein said Oxyorthosilicate scintillation crystals are annealed in an iridium crucible, wherein an iridium washer is disposed on top of said iridium crucible whereby the thermal environment within said iridium crucible is improved and further wherein said method further comprises the step of disposing an iridium spacer between each said Oxyorthosilicate scintillation crystal to be annealed.

6. The method of claim 4 wherein said selected period of time for increasing said temperature and said selected period of time for decreasing said temperature is approximately four hours per each approximately 10 mm thickness of said Oxyorthosilicate scintillation crystal.

7. The method of claim 4 wherein said annealing temperature is in a range of approximately 1400° Celsius to approximately 1800° Celsius.

8. The method of claim 4 wherein said Oxyorthosilicate scintillation crystal is selected from a group consisting of Lutetium Oxyorthosilicate, Yttrium Oxyorthosilicate, Lutetium Gadolinium Oxyorthosilicate and Lutetium Yttrium Oxyorthosilicate.

9. A method for improving the light yield of a Oxyorthosilicate compound scintillation crystal comprising the steps of;
arranging Oxyorthosilicate scintillation crystals to be annealed in a crucible in an selected, identifiable manner, wherein said Oxyorthosilicate scintillation crystals are in spaced relation and an iridium spacer is disposed between each Oxyorthosilicate scintillation crystal to be annealed for preventing fusion of crystals in close proximity to one another, wherein said Oxyorthosilicate scintillation crystals are selected from a group consisting of Lutetium Oxyorthosilicate, Yttrium Oxyorthosilicate, Lutetium Gadolinium Oxyorthosilicate and Lutetium Yttrium Oxyorthosilicate;
locating said crucible within a furnace chamber;
increasing temperature in said furnace chamber linearly from room temperature to said annealing temperature over a period of time of approximately four hours per each approximately 10 mm thickness of said Oxyorthosilicate scintillation crystal;
holding said annealing temperature within said furnace chamber for approximately four hours per each 10 mm thickness of said Oxyorthosilicate scintillation crystal;
decreasing said temperature within said furnace chamber to room temperature over a selected period of time of approximately four hours per each approximately 10 mm thickness of said Oxyorthosilicate scintillation crystal; and
removing said Oxyorthosilicate scintillation crystals from said furnace.

10. The method of claim 9 wherein said Oxyorthosilicate scintillation crystals are annealed in an iridium crucible and further wherein an iridium washer is disposed on top of said crucible whereby the thermal environment within said crucible is improved.

11. The method of claim 9 wherein said annealing temperature is in a range of approximately 1400° Celsius to approximately 1800° Celsius.
